(19) United States
(12) Patent Application Publication
(10) Pub. No.: US 2017/0084510 A1
(43) Pub. Date: Mar. 23, 2017

(54) A Wide Band Gap Semiconductor Device and Its Fabrication Process

(71) Applicants: Masahiro Hoshino, Kawaguchi, Saitama (JP); Lenian Zhang, Taizhou, Zhejiang (CN)

(72) Inventors: Masahiro Hoshino, Kawaguchi, Saitama (JP); Lenian Zhang, Taizhou, Zhejiang (CN)

(73) Assignees: Taizhou Beyond Technology Co., Ltd., Taizhou City, Zhejiang (CN); Masahiro Hoshino, Kawaguchi, Saitama (JP)

(21) Appl. No.: 15/312,622

(22) PCT Filed: Feb. 12, 2015
(86) PCT No.: PCT/CN2015/072909

§ 371 Date: Nov. 18, 2016

(30) Foreign Application Priority Data
Aug. 4, 2014 (CN) CN 201410379970.7

(51) Int. Cl. H01L 23/14; H01L 23/367; H01L 23/00; H01L 29/16

(52) U.S. Cl. CPC H01L 23/147; H01L 29/1608; H01L 23/3675; H01L 24/32; H01L 24/83; H01L 2224/83385; H01L 2224/8384

(57) ABSTRACT

The present invention provides a wide band gap semiconductor device and its fabrication process, and pertains to the technical field of semiconductor fabrication technology. It resolves the current issue that the wide band gap semiconductor devices are easy to be affected by thermal expansion. The present wide band gap semiconductor device comprises a chip with a substrate made of a wide band gap semiconductor material, and a base mount made of a wide band gap semiconductor material. In addition, there is a recessed slot structure designed on the base mount to hold the chip. The present invention also provides a fabrication process for wide band gap semiconductor devices. In the wide band gap semiconductor device described in the present invention, both of the base mount and the substrate of the chip are made of wide band gap semiconductor materials, which can achieve the purpose of rapid heat transfer.

### BACKGROUND OF THE INVENTION

Field of Invention

The present invention pertains to the technical field of semiconductor fabrication technology, relates to a semiconductor device and its fabrication process, and particularly to a wide band gap semiconductor made of wide band gap semiconductor materials and its fabrication process.

Related Art

A wide band gap semiconductor material is semiconductor material with the band gap no less than 2.3 eV, which is called the third generation semiconductor materials. It mainly includes diamond, silicon carbide, gallium nitride, etc. Compared to the semiconductor materials of the first and the second generations, the semiconductor materials of the third generation have the characteristics of a wide band gap, a high electron saturation drift velocity, a low dielectric constant, a high electrical conductivity, etc. They have excellent properties and they are potentially promising.

In the current chip technology, the bottom of a chip needs to be successively attached to a copper heat sink layer, an insulation layer, a copper heat sink layer, a connection layer for welding, and a copper heat sink layer. In order to enhance the capacity of heat transfer, heat sinks are also required to be fixed on it at last. The insulation layer and the metal heat sink layers are indispensable heat transfer structures in semiconductor devices. The insulation layer is used to lead the positive and negative poles, while multiple heat sink layers are used to ensure the heat transfer efficiency of the chip.

Although wide band gap semiconductor devices have a good application prospect, for the current wide band gap semiconductor devices made of wide band gap semiconductor materials, because of the high price of the substrate, their popularization is very slow. Besides, since the insulation layer, the copper heat sink layer and the substrate of the chip are made of different materials, their thermal expansion coefficients are different too. Therefore, the semiconductor devices or modules need to adjust the thermal expansion coefficients and the thermal transfer coefficients of their accessories. This leads to a complex structure and a high price of semiconductor devices or modules, and the reliability is low, because a wide band gap semiconductor device can work normally at a high temperature of 350° C., however, at the high and low temperatures when switched on or off, the semiconductor device's accessories will be subjected to thermal fatigue and the reliability of the semiconductor device decreases significantly. This shortens the service life of the device, and even the industrialization cannot be realized.

### SUMMARY OF THE INVENTION

One object of one embodiment of the present invention is to avoid the technical issues stated above, and to provide a wide band gap semiconductor device.

The technical issue which one embodiment of the present invention is aiming to resolve is how to eliminate the effect resulting from different thermal expansions of various parts in a wide band gap semiconductor device, and to improve its capacity of heat transfer at the same time.

The object of one embodiment of the present invention can be achieved by the following technical proposal:

A wide band gap semiconductor device is characterized in that, it comprises a chip with a substrate made of a wide band gap semiconductor material, and a base mount made of a wide band gap semiconductor material. In addition, there is a recessed slot structure designed on the base mount to hold and position the chip.

The substrate of the chip in the wide band gap semiconductor device is made of a wide band gap semiconductor material, and the base mount is made of a wide band gap semiconductor material as well. In this way, a single base mount can replace the current insulation layer and multiple metal layers, and realize double functions of insulation and heat transfer, so the structure is significantly simplified. Also, since both of the base mount and the substrate of the chip are made of wide band gap semiconductor materials, their heat transfer coefficient and the thermal expansion coefficient are the same or similar. This eliminates the issue that the difference in the thermal expansion coefficients of various parts of the wide band gap semiconductor device is huge. And it need not match the thermal expansion coefficients of the base mount, so the structure of the base mount is simplified. A recessed slot is designed on the base mount to hold the chip. The chip can be positioned quickly and accurately through the recessed slot, and the chip can be fixed tightly at the same time.

In the above wide band gap semiconductor device, the base mount and the chip are connected by a thermally conductive layer. The thermally conductive layer is fabricated by sintering the metal powder filled in the recessed slot structure, or fixed by welding. The thermally conductive layer between the base mount and the chip transfers the heat and thus the heat transfer function is realized. This ensures the heat transfer effect of the wide band gap semiconductor device. It can be fabricated by sintering the metal powder in the recessed slot structure, or by spot welding or reflow soldering. The recessed slot structure can locate the thermally conductive layer, and restrict the degree of freedom of its perimeter. The connection described above is fixed and reliable. It is hard for the thermally conductive layer to slide or detach, and convenient for the chip to be fixed.

In the above wide band semiconductor device, the thermally conductive layer is electrically conductive. While the thermally conductive layer is able to transfer the heat, it also has a good electrical conductivity. This can simplify the structure of the semiconductor device.

In the above wide band gap semiconductor device, the metal powder is metallic silver powder. The thermally conductive layer is preferably made of silver, because of its high cost performance. The thermal conductivities of tin, copper, aluminum, etc. are not as good as that of silver. Gold is expensive and increases the cost. When using silver powder, the smaller its grain size is, the better it is. When the silver powder is at nanoscale, the sintering temperature can decrease by 30° C.˜80° C., compared to using the powder at micron scale.

In the above wide band gap semiconductor device, the thickness of the thermally conductive layer is 10 μm˜75 μm. The heat transfer effect shall be ensured, while the fabrication cost of the thermally conductive layer shall be taken into account as well. After a comprehensive consideration, this thickness has a high cost performance, and meets the requirements.

In the above wide band gap semiconductor device, the substrate material of the chip and the material of the base mount have the same chemical composition. The same chemical composition of the wide band gap materials ensures that the thermal expansion coefficient and the heat transfer coefficient are almost the same. During the heat transfer, no deformations or detachments of the material, which happens in the current technology as a result from different thermal expansion coefficients of different materials, will happen. No extra materials will be required to adjust the thermal expansion, and this simplifies the semiconductor device.

In the above wide band gap semiconductor device, the base mount comprises a conductive wide band gap material layer and a semi-insulating wide band gap material layer. The conductive wide band gap material layer overlaps the semi-insulating wide band gap material layer, or, in multiple layers, they overlap each other alternatingly. The conductive wide band gap material layer on the base mount ensures its electrical conductivity, and makes the chip work normally, while the semi-insulating wide band gap material layer blocks the current, separates the positive and negative poles and avoids a short circuit. The adoption of multiple layers overlapping each other alternatingly further enhances the heat sink effect.

The conductivity of conductive wide band gap materials is obtained by doping boron, nitride, etc. into the wide band gap materials during the doping process of the fabrication of semiconductor devices. It is used for making chips. The semi-insulating wide band gap material can be semi-insulating SiC, Ca₂O₃, etc.

In the above wide band gap semiconductor device, the substrate of the chip is made of conductive wide band gap material, and the base mount is made of semi-insulating wide band gap material. The substrate of the chip and the base mount are connected by the thermally conductive layer. The thermally conductive layer can conduct electricity for the chip, transfer and dissipate the heat.

In the above wide band gap semiconductor device, between the conductive wide band gap material layer and the semi-insulating wide band gap material layer, a conductor layer is arranged, which is capable of conducting heat and electricity. The conductor can effectively ensure the continuity and reliability of the heat transfer on the base mount, and it can also be used to conduct electricity. Meanwhile, it can lead the positive or negative pole.

In the above wide band gap semiconductor device, the chip has electrically conductive metal layer on its bottom, and the metal layer has a protruding and/or recessing structure. By connecting the chip to the thermally conductive layer with the metal layer on chip, the chip is electrically connected to the base mount. The position of the chip's electrode may be changed, and hence the thermally conductive layer can play a better heat transfer effect, so that highly effective heat transfer is ensured under any circumstances. The metal layer on the chip has a protruding and/or recessing structure which can increase the contact area, improve the electrical conductivity and the thermal conductivity. The metal layer can be silver layer, gold layer or nickel layer, which has a good electrical conductivity.

In the above wide band gap semiconductor device, the protruding and/or recessing structure of the metal layer on the chip means the pits uniformly distributed on the surface of the metal layer on chip, or the projecting barbs uniformly distributed on the surface of the metal layer on chip. The adoption of spaced pits or projecting barbs can increase the contact area, which makes the contact between the chip and the base mount more fixed. Of course, other means of deformation can be used to achieve the same purpose, but the result is largely the same.

In the above wide band gap semiconductor device, the internal side walls of the recessed slot structure are outward inclined, forming a recessed slot with a wider opening and a narrower bottom. As for the inclination angle, relative to the vertical plane at 90 degrees, the outward inclination angle is within 10°, inclusively. The best angle is 8°. The adoption of a recessed slot with a wide opening and a narrow bottom is convenient to fill metal powder in the recessed slot structure, so as to facilitate the subsequent fixation by sintering and welding. The inclination angle is 8° preferably. The contact area between the thermally conductive layer and the wide band gap semiconductor chip is large, which facilitates a timely heat transfer and can ensure that the heat transfer effect of the thermally conductive layer is not affected.

As the first proposal for the recessed slot structure, in above the wide band gap semiconductor device, the recessed slot structure comprises a recessed slot designed on the base mount, and a metal conductor on the recessed slot. The metal conductor on the recessed slot fills up the recessed slot, and further extends to the outside of the recessed slot. There is a recessed slot on the conductor designed on the metal conductor on the recessed slot. The metal conductor on the recessed slot fills up the recessed slot to the opening of the slot, which ensures the fix and stability of the conductor on the base mount. The metal conductor on the recessed slot can conduct electricity. The contact area between the metal conductor recessed slot and the base mount is large, which can ensure a sufficiently stable electrical conductivity, as well as the stability and high efficiency of the heat transfer. A similar recessed slot on the conductor is also formed on the metal conductor recessed slot, which facilitates the installation and fixation of the thermally conductive layer, and increases the firmness.

In the above wide band gap semiconductor device, the surface of the metal layer recessed slot has a protruding and/or recessing structure. The protruding and/or recessing structure can increase the contact area, and improve the effect of conducting electricity and transferring heat.

As the second proposal for the recessed slot structure, in the above wide band gap semiconductor device, the bottom of the recessed slot structure and its internal side walls have part or whole metal layer recessed slot. The metal layer on the recessed slot extends to the surfaces of the base mount around the slot opening of the recessed slot structure. The areas of the internal side walls of the recessed slot structure, as well as the base mount are big. After the metal layer on the recessed slot is plated on them, the electrical conductivity and heat transfer from the chip to the base mount, through the thermally conductive layer, are improved. The contact area is sufficiently utilized to ensure the stability of the electrical conductivity and heat transfer. With the same effect as in the first proposal, the metal layer on the recessed slot can conduct electricity, and ensures the stability and high efficiency of the heat transfer effect. In addition, the metal layer on the recessed slot only covers the side walls and the bottom of the recessed slot. The thickness is small, so the material used to fabricate the metal layer on the recessed slot is saved, and hence the production cost is saved.

In the above wide band gap semiconductor device, the metal layer on the recessed slot mentioned above consists of a single layer or multiple layers, and the top layer of the metal layer on the recessed slot has a protruding and/or recessing structure. The protruding and/or recessing structure can increase the contact area, improve the effect of electrical conductivity and the heat transfer, and enhance the firmness of the connection to other parts.

In the above wide band gap semiconductor device, there is a distance, denoted as L, between position a, where the outward inclination of the bottom of the chip will extend to and intersect with the bottom of the base mount, and position b, the outer edge of the base mount. According to the diffusion area and range of the heat transfer, such a design can ensure the area and zone for the heat transfer, so as to ensure the effect of the heat transfer. If the extension of the inclination doesn't reach the bottom of the base mount, the heat will accumulate at the sides of the base mount and can't be timely dissipated through the bottom of the base mount.

In the above wide band gap semiconductor device, the outer inclination from the bottom of the chip will extend to and intersect with the bottom of the base mount, at an angle within the range of 25°˜65°. When the heat transfers to surroundings, it mainly transfers downward through the thermally conductive layer. In order to obtain a good effect of heat transfer, the rim of the base mount is large enough to ensure the heat transfer. Based on a comprehensive consideration on the manufacturing cost and the space occupation, the reference angle is designed from the point of view of the heat transfer direction, to achieve a high cost performance. Within the range of the angle, 45° is preferred.

In the above wide band gap semiconductor device, there is a distance, denoted as L′, between position c, where the outward inclination from the bottom of the chip will extend to and intersect with the top of the base mount, and position d, the outer edge of the metal layer on the recessed slot. According to the diffusion area and range of the heat transfer, this can ensure a smooth heat transfer, so as to achieve a good effect of the heat transfer.

As an improvement on the base mount, in the above wide band gap semiconductor device, heat sinks are designed on the bottom of the base mount. When the heat from the wide band gap semiconductor chip transfers to the base mount, it's then dissipated through the heat sinks. This maintains the chip working at a normal temperature level. The reliability and the service life of the device are largely improved.

In the above wide band gap semiconductor device, the material of the wide band gap semiconductor is silicon carbide.

One embodiment of the present invention also provides a fabrication process for the wide band gap semiconductor devices. It is characterized in that:

A recessed slot structure is designed on the base mount made of wide band gap semiconductor materials. A thermally conductive layer is formed by filling up the recessed slot structure with metal powder, and a chip with the substrate made of wide band gap semiconductor materials is placed on the thermally conductive layer by the recessed slot structure. By sintering or welding, the capacity of dissipating the heat and/or conducting electricity arises between the metal and the chip, and between metal and the base mount, and hence a wide band gap semiconductor device is formed.

In the above fabrication process for wide band gap semiconductor devices, the pressure sintering process or the vacuum sintering process is adopted in the sintering process.

In the above fabrication process for wide band gap semiconductor devices, the thickness of the thermally conductive layer is controlled by the slot depth of the recessed slot structure.

In the above fabrication process for wide band gap semiconductor devices, the sintering process is implemented in an inert gas atmosphere, at 230° C.˜330° C., by imposing a 5˜40 MPa/cm² pressure on the chip and continuously heating for 20˜30 minutes.

In the above fabrication process for wide band gap semiconductor devices, as a preferred proposal, the sintering process is implemented in an inert gas atmosphere, at 250° C., by imposing a 30 MPa/cm² pressure on the chip and continuously heating for 30 minutes.

In the above fabrication process for wide band gap semiconductor devices, when the particle size of the metal powder is at nanoscale, the sintering process is implemented in an inert gas atmosphere, at 180° C.˜280° C., by imposing a 5˜40 MPa/cm² pressure on the chip and continuously heating for 20˜35 minutes. When the silver powder is at nanoscale, the sintering temperature can decrease by 30° C.˜80° C., compared to using the powder at micron scale.

In the above fabrication process for wide band gap semiconductor devices, before the sintering or welding process, metal layer on the chip, which is capable of conducting electricity, is plated on the bottom of the chip in advance, and the metal layer on the chip has a protruding and/or recessing structure. The chip is electrically connected to the base mount through the metal layer on the chip. The position of the chip's electrode may be changed, and hence the thermally conductive layer can play a better heat transfer effect, so that highly effective heat transfer is ensured under any circumstances.

In the above fabrication process for wide band gap semiconductor devices, before the sintering or welding process, a recessed slot is made on the base mount, and then the metal layer on the recessed slot is plated on the recessed slot. The recessed slot is designed with a wider opening and a narrower bottom, and the metal layer on the recessed slot has a protruding and/or recessing structure. The recessed slot can have a location and fixation effect. When the chip is fixed into the recessed slot, the locating is easy and accurate. Also, the thermally conductive layer is sintered or welded in the recessed slot. Its position is confined, and the degree of freedom of its perimeter is restricted. The connection is fixed and reliable. It's hard for the thermally conductive layer to slide off. Meanwhile, this ensures the heat transfer effect of the wide band gap semiconductor chip. The protruding and/or recessing structure on the metal layer on the recessed slot can increase the contact area, which further enhances the electrical conductivity and the heat transfer effect.

Compared with the prior art, it is characterized in that:

Both of the base mount and the substrate of the chip are made of wide band gap semiconductor materials. The heat generated by the chip can directly transfers to the base mount and then dissipates. A wide band gap semiconductor material with a good heat transfer performance can achieve the purpose of rapid heat transfer. Also, since the thermal expansion coefficient and the heat transfer coefficient are largely the same, no extra materials are required to be added to the bottom or accessories to adjust the thermal expansion coefficients. This extremely simplifies the structure of the wide band gap semiconductor device, reduces the effect of the thermal expansion, and improves the stability. The chip is fixed on the base mount through the recessed slot on the base mount. It can be located quickly and accurately, and it is fixed tightly. Either the metal layer on the recessed slot or the metal conductor on the recessed slot in the recessed slot can transfer the heat generated by the chip to the outside of the chip, playing an effect of improving the heat transfer of the chip.

### BRIEF DESCRIPTION OF THE DRAWINGS

FIG. 1 is the stereoscopic schematic view of one embodiment of the present wide band gap semiconductor device.

FIG. 2 is the stereoscopic schematic view of the base mount of one embodiment of the present wide band gap semiconductor device.

FIG. 3 is the sectional schematic view of the present wide band gap semiconductor device after the sintering process of a first embodiment.

FIG. 4 is the sectional schematic view of the present wide band gap semiconductor device after the sintering process of a second embodiment.

FIG. 5 is the sectional schematic view of the present wide band gap semiconductor device of a third embodiment.

FIG. 6 is the sectional schematic view of the present wide band gap semiconductor device before the sintering process of a fourth embodiment.

FIG. 7 is the sectional schematic view of the present wide band gap semiconductor device before the sintering process of a fifth embodiment.

FIG. 8 is the stereoscopic schematic view of the present wide band gap semiconductor device of a sixth embodiment.

### DETAILED DESCRIPTION OF THE INVENTION

Embodiments of this invention will be described below and the technical solutions of the invention will be further illustrated in connection with the accompanying figures. However, the present invention shall not be limited to these embodiments.

### First Embodiment

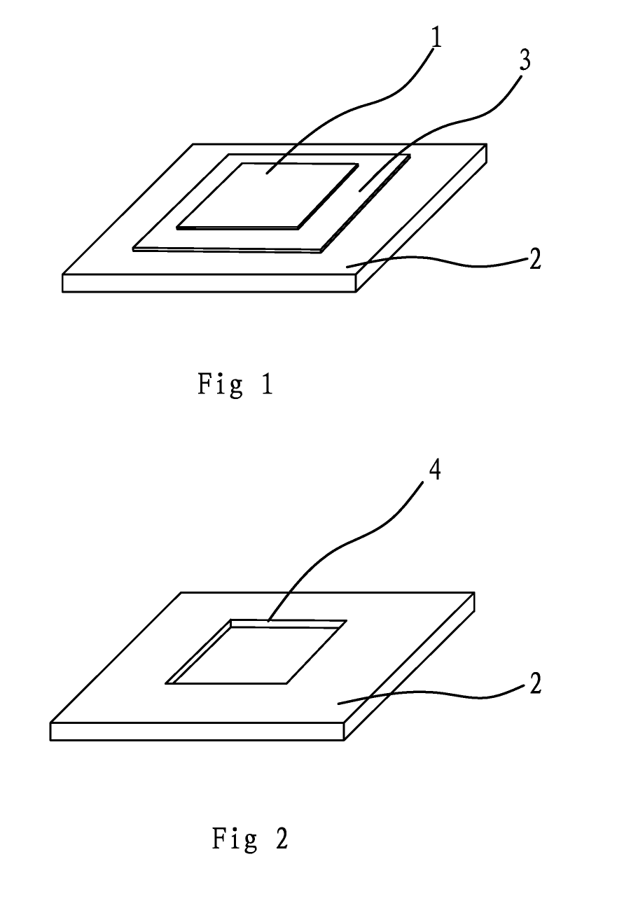

As shown in FIGS. 1 and 2, the present wide band gap semiconductor device comprises a chip (1) with a substrate made of a wide band gap semiconductor material, and a base mount (2) made of a wide band gap semiconductor material. In addition, there is a recessed slot structure (4) designed on the base mount (2) to hold the chip (1), and the substrate material of the chip (1) and the material of the base mount (2) have the same chemical composition. Both of the base mount (2) and the substrate of the chip (1) are made of silicon carbide, a wide band gap semiconductor material. The heat generated by the chip (1) can directly transfers to the base mount (2) and then dissipates. Silicon carbide, a wide band gap semiconductor material with a good heat transfer performance, can achieve the rapid heat transfer. Also, since the thermal expansion coefficient is largely the same, no extra materials are required to adjust the thermal expansion coefficients on the bottom of the chip (1) or accessories. This extremely simplifies the structure of the wide band gap semiconductor device, reduces the effect by the thermal expansion, and improves the stability to transfer heat and conduct electricity. The chip (1) is fixed on the base mount (2) through the recessed slot structure (4) on the base mount (2). It can be located quickly and accurately, and it is fixed tightly. By adjusting the location and depth of the recessed slot structure (4), the location and thickness of the thermally conductive layer (3) can be controlled during the sintering process.

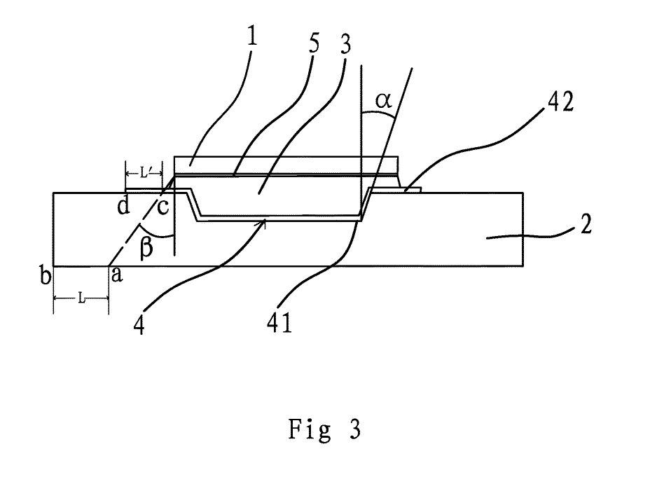

Specifically, as shown in FIGS. 2 and 3, the internal side walls of the recessed slot structure (4) are outward inclined, forming a recessed slot with a wider opening and a narrower bottom. As for the inclination angle, relative to the vertical plane at 90 degrees, the outward inclination angle α is 8°. In general, the inclination angle α is within 10°, inclusively. The bottom of the recessed slot structure (4) and its internal side walls in whole have metal layer on recessed slot (42). The metal layer on recessed slot (42) extends to the surfaces of the base mount (2) around the slot opening of the recessed slot structure (4). The metal layer on recessed slot (42) is silver layer. As an alternative, the recessed slot structure (4) may comprise a bottom and part of its internal side walls with metal layer on recessed slot (42). Namely, one side or two sides or three sides among the four sides are plated.

As shown in FIG. 3, the substrate of the chip (1) is made of conductive wide band gap material, and the base mount (2) is made of semi-insulating wide band gap material. The chip (1) and the base mount (2) are connected by the thermally conductive layer (3). The thermally conductive layer (3) is fabricated by sintering the silver powder filled in the recessed slot structure (4). By adjusting the location and depth of the recessed slot structure (4), the location and thickness of the thermally conductive layer (3) can be controlled during the sintering process. Other than sintering, the thermally conductive layer (3) may also be fixed by welding. Specifically, the welding method would be spot welding or reflow soldering. The thickness of the thermally conductive layer (3) is 20 μm. In general, the thickness of the thermally conductive layer (3) could be any value within the range of 10 μm˜75 μm. As shown in FIG. 3, there is a distance, denoted as L, between position a, where the outward inclination of the bottom of the chip (1) will extend to and intersect with the bottom of the base mount (2), and position b, the outer edge of the base mount (2). The inclination angle β at which the outward inclination of the bottom of the chip (1) will extend to and intersect with the bottom of the base mount (2) is 45°. In general, β could be any angle within the range of 25°˜65°. There is a distance, denoted as L′, between position c, where the outward inclination from the bottom of the chip (1) will extend to and intersect with the top of the base mount (2), and position d, the outer edge of the metal layer on recessed slot (42). This structure makes the heat reach the bottom, instead of accumulate at the middle part of the sides of the base mount, and thus the heat doesn't dissipate in a timely manner.

In this embodiment, metallic silver is preferably chosen as the thermally conductive layer (3) of the recessed slot structure (4). The smaller its grain size is, the better it is. When the silver powder is at nanoscale, the sintering temperature can decrease by 30° C.˜80° C., compared to using the powder at micron scale. The recessed slot structure (4) can have a location and fixation effect. When the thermally conductive layer (3) and the chip (1) are fixed into the recessed slot structure (4), it's easy and accurate to locate them. Also, the degree of freedom of their perimeters is restricted. The connection is fixed and reliable. It's hard for them to slide off. The thermally conductive layer is made of silver, which has a good heat conductivity and heat conductivity. When it connects the base mount (2) to the chip (1), the heat transfer effect on the chip (1) can be ensured. The proposal stated above reduces the thermal fatigue of the metal in the wide band gap semiconductor device, raises its heat resistance, improves its heat transfer performance, and at the same time ensures its electrical conductivity. It significantly reduces the previously needed materials to adjust the thermal expansion coefficients of various accessories, and much simplifies the structure. Besides by adjusting and matching the thermal expansion coefficients of materials of various accessories, even at a high temperature, the reliability is further significantly improved, and the cost is reduced dramatically. By using the composition, structure, material, no matter how bad the electrical conduction and insulation performance of the substrate of the chip (1) and the base mount (2) are, no matter how they are combined, a high heat transfer performance can be provided. Also, since no adjustment to the thermal expansion coefficient is required, the service life and the reliability of the device are dramatically improved.

### Second Embodiment

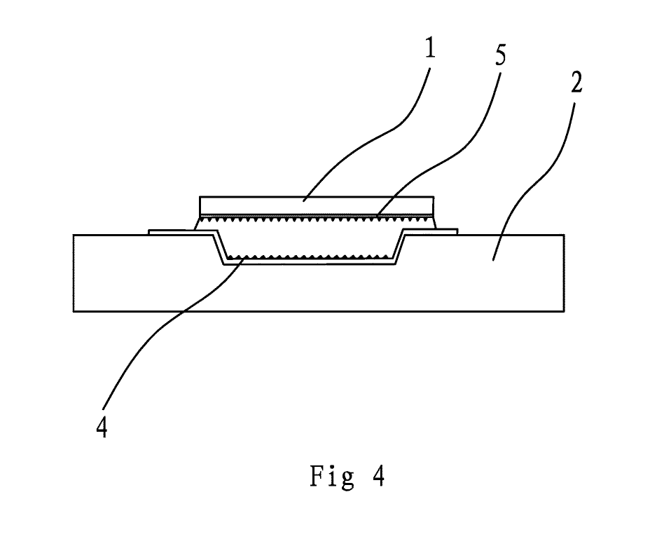

As shown in FIG. 4, the composition in this embodiment is largely the same as that in the first embodiment. The differences are:

There is electrical conductive metal layer on chip (5) on the bottom of the chip (1), and the metal layer on chip (5) has a protruding and/or recessing structure. The protruding and/or recessing structure of the metal layer on chip (5) means pits uniformly distributed on the surface of the metal layer on chip (5). The adoption of spaced pits can increase the contact area, which makes the contact between the chip (1) and the base mount (2) more fixed. Of course, projecting barbs uniformly distributed on the surface of the metal layer on chip (5), or other means of deformation can also be used to achieve the same purpose. The protruding and/or recessing structure can improve the effect of conducting electricity and transferring heat. Similarly, the metal layer on recessed slot (42) on the base mount (2) has a single layer, and the metal layer on recessed slot (42) has a protruding and/or recessing structure. The protruding and/or recessing structure means pits uniformly distributed on the surface of the metal layer on recessed slot (42). Of course, the protruding and/or recessing structure stated above can also be distributed non-uniformly.

### Third Embodiment

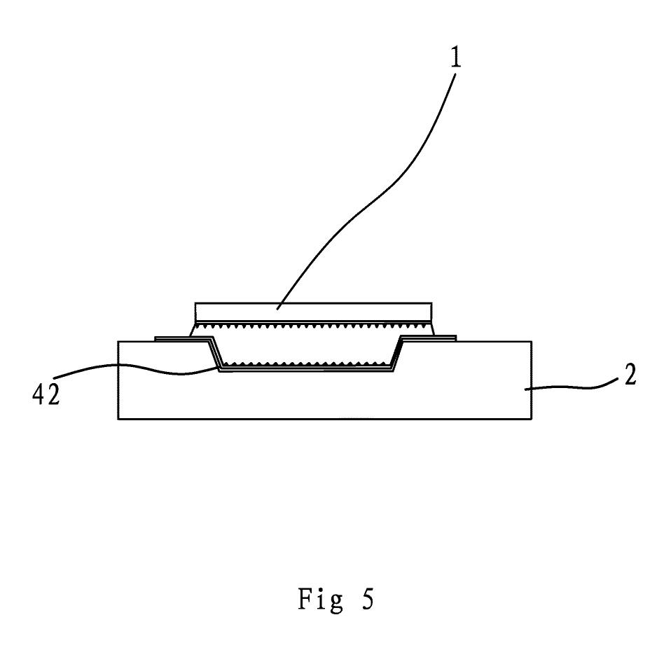

As shown in FIG. 5, the composition in this embodiment is largely the same as that in the first and second embodiments. The differences are:

As shown in FIG. 5, the metal layer on recessed slot (42) has multiple layers, and the top layer of the metal layer on recessed slot (42) has a protruding and/or recessing structure. The protruding and/or recessing structure means pits uniformly distributed on the surface of the metal layer on recessed slot (42). The adoption of spaced pits can increase the contact area, which makes the contact between the chip (1) and the base mount (2) more fixed. Of course, projecting barbs uniformly distributed on the surface of the metal layer on recessed slot (42), or other means of deformation can also be used to achieve the same purpose. The effect is largely the same. It can improve the effect of electrical conductivity and thermal conductivity.

### Fourth Embodiment

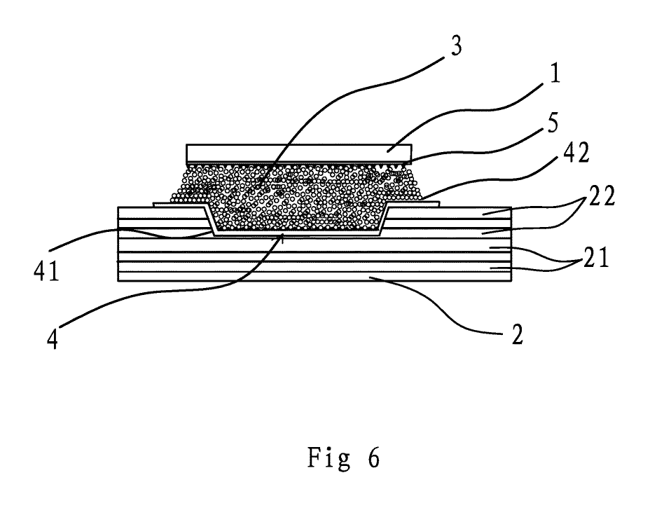

As shown in FIG. 6, the composition in this embodiment is largely the same as that in the first, second, and third embodiments. The differences are:

The base mount (2) comprises a conductive wide band gap material layer (21) and a semi-insulating wide band gap material layer (22). The conductive wide band gap material layer (21) overlaps the semi-insulating wide band gap material layer (22), or, in multiple layers, they overlap each other alternatingly. Between the conductive wide band gap material layer (21) and the semi-insulating wide band gap material layer (22), a conductor layer is arranged, which is capable of conducting heat and electricity. By decreasing the electrical conductivity successively through the thermally conductive layer (3), the semi-insulating wide band gap material layer (22) and the conductive wide band gap material layer (21), the heat transfer effect accelerates. The overlapping parts between the conductive wide band gap material layer (21) and the semi-insulating wide band gap material layer (22) consist of a conductor. The conductor can effectively ensure that the heat generated by the chip quickly passes through the semi-insulating wide band gap material layer (22) and the conductive wide band gap material layer (21). At present, the cost of the conductive wide band gap material is lower than that of the semi-insulating wide band gap material layer. This embodiment can effectively reduce the cost of the wide band gap device.

### Fifth Embodiment

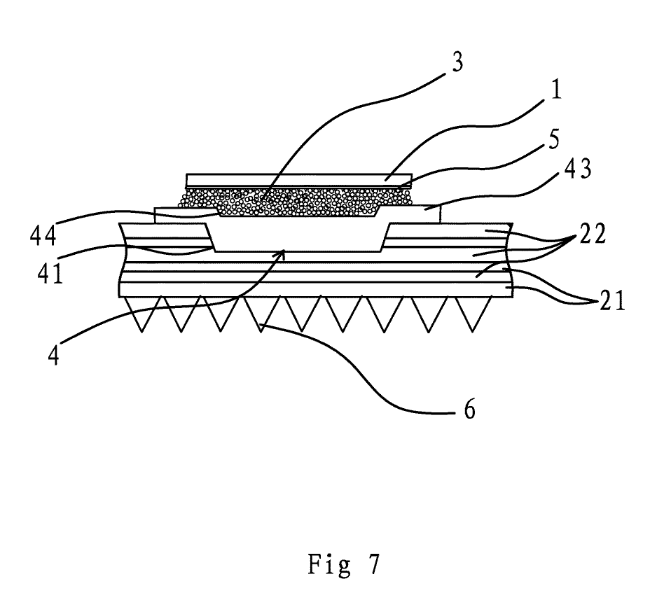

As shown in FIG. 7 the composition in this embodiment is largely the same as those in the first, second, third, and fourth embodiments. The differences are:

As the second embodiment for the recessed slot structure (4), the recessed slot structure (4) comprises a recessed slot (41) designed on the base mount (2) and a metal conductor on recessed slot (43). The metal conductor on recessed slot (43) fills up the recessed slot (41), and further extends to the outside of the recessed slot (41). There is a recessed slot on conductor (44) designed on the metal conductor on recessed slot (43). The bottom of the recessed slot on conductor (44) is above the top of the base mount (2), and the metal conductor on recessed slot (43) has a protruding and/or recessing structure on its surface. The metal conductor on recessed slot fills up the recessed slot to the opening of the slot, which ensures the fix and stability of the conductor on the base mount. The metal conductor on recessed slot (43) can conduct electricity. The contact area between the metal conductor on recessed slot (43) and the base mount (2) is large, which can ensure a sufficiently stable electrical conductivity, as well as the stability and high efficiency of the heat transfer. A similar recessed slot on conductor (44) is also formed on the metal conductor on recessed slot (43), which facilitates the installation and fixation of the thermally conductive layer (3), and increases the firmness. The protruding and/or recessing structure can increase the contact area, and improve the effect of conducting electricity and transferring heat.

### Sixth Embodiment

The composition in this embodiment is largely the same as any one of the above five embodiments. The differences are:

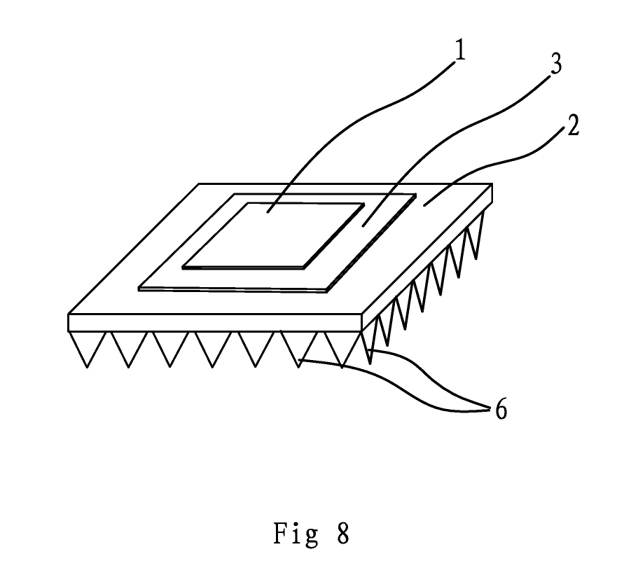

As shown in FIG. 8, heat sinks (6) are arranged on the bottom of the base mount (2). When the heat generated by the chip (1) transfers to the base mount (2), it is then dissipated through the heat sinks (6) in a timely manner. This maintains the chip (1) working at a normal temperature level. The reliability and the service life of the device are largely improved.

### Seventh Embodiment

The present embodiment provides a fabrication process for wide band gap semiconductor devices. Specifically, a recessed slot structure (4) is designed on the base mount (2) made of wide band gap semiconductor materials. A thermally conductive layer (3) is in the recessed slot structure (4). The thermally conductive layer (3) is formed by filling up the recessed slot structure (4) with metal powder and is fixed on the recessed slot structure (4) by sintering. Or the thermally conductive layer (3) is fixed on recessed slot structure (4) by welding, and then a chip (1) is placed on the thermally conductive layer (3). By sintering or welding, the thermally conductive layer (3) and the chip (1) are connected, the thermally conductive layer (3) and the base mount (2) are connected, and hence a wide band gap semiconductor device with the capacity of conducting electricity is formed. The substrate of the chip (1) is also made of wide band gap semiconductor materials. In the present embodiment, the thermally conductive layer (3) is made of metallic silver. Before the sintering process, metal layer on chip (5), which is capable of conducting electricity, is plated on the bottom of the chip (1) in advance, and the metal layer on chip (5) has a protruding and/or recessing structure. Before the sintering process, a recessed slot (41) is made on the base mount (2) first, and then the metal layer on recessed slot (42) is plated on the recessed slot (41), in order to form the recessed slot structure (4). The recessed slot (41) is designed as a recessed slot, with a wider opening and a narrower bottom, and the metal layer on recessed slot (42) has a protruding and/or recessing structure. The sintering process is implemented in an inert gas atmosphere, at 230° C., by imposing a 5 MPa/cm² pressure on the chip (1) and continuously heating for 20 minutes.

### Eighth Embodiment

The present embodiment is largely the same as the seventh embodiment. The differences are:

As an alternative process, the sintering process is implemented in an inert gas atmosphere, at 330° C., by imposing a 40 MPa/cm² pressure on the chip (1) and continuously heating for 35 minutes.

### Ninth Embodiment

The present embodiment is largely the same as the seventh and eighth embodiments. The differences are:

As a preferred proposal, the sintering process is implemented in an inert gas atmosphere, at 250° C., by imposing a 30 MPa/cm² pressure on the chip and continuously heating for 30 minutes.

### Tenth Embodiment

The present embodiment is largely the same as the seventh, eighth, and ninth embodiments. The differences are:

In the present embodiment, the grain size of the metallic silver particles is at nanoscale. The sintering temperature can decrease by 30° C.˜80° C., compared to that in the seventh, eighth, and ninth embodiments, according to the grain sizes.

The description of the preferred embodiments thereof serves only as an illustration of the spirit of the invention. It will be understood by those skilled in the art that various changes or supplements in form and details may be made therein without departing from the spirit and scope of the invention as defined by the appended claims.

### LIST OF REFERENCE NUMERALS

1 Chip
2 Base Mount
21 Conductive Wide Band Gap Material Layer
22 Semi-Insulating Wide Band Gap Material Layer
3 Thermally Conductive Layer
4 Recessed Slot Structure
41 Recessed Slot
42 Metal Layer on Recessed Slot
43 Metal Conductor on Recessed Slot
44 Recessed Slot on Conductor
5 Metal Layer on Chip
6 Heat Sink

What is claimed is:

1. A wide band gap semiconductor device comprising:
a chip (1) with a substrate made of a wide band gap semiconductor material;
a base mount (2) made of a wide band gap semiconductor material; and
a recessed slot structure (4) designed on the base mount (2) to hold and position the chip (1).

2. The wide band gap semiconductor device as claimed in claim 1 wherein the base mount (2) and the chip (1) are connected by a thermally conductive layer (3), the thermally conductive layer (3) is fabricated by sintering the metal powder filled in the recessed slot structure (4), or fixed by welding.

3. The wide band gap semiconductor device as claimed in claim 2 wherein the thermally conductive layer (3) is electrically conductive.

4. The wide band gap semiconductor device as claimed in claim 2 wherein the metal powder is metallic silver powder.

5. The wide band gap semiconductor device as claimed in claim 3 wherein a thickness of the thermally conductive layer (3) is 10 μm to 75 μm.

6. The wide band gap semiconductor device as claimed in claim 1 wherein a substrate material of the chip (1) and a material of the base mount (2) have a same chemical composition.

7. The wide band gap semiconductor device as claimed in claim 6 wherein the base mount (2) comprises a conductive wide band gap material layer (21) and a semi-insulating wide band gap material layer (22), the conductive wide band gap material layer (21) overlaps the semi-insulating wide band gap material layer (22), or they overlap each other alternately in multiple layers.

8. The wide band gap semiconductor device as claimed in claim 3 wherein the substrate of the chip (1) is made of conductive wide band gap material, the base mount (2) is made of semi-insulating wide band gap material, the substrate of the chip (1) and the base mount (2) are connected by the thermally conductive layer (3).

9. The wide band gap semiconductor device as claimed in claim 7 wherein between the conductive wide band gap material layer (21) and the semi-insulating wide band gap material layer (22) is arranged a conductor layer that is capable of conducting heat and electricity.

10. The wide band gap semiconductor device as claimed in claim 2 wherein the chip (1) has electrically conductive metal layer on chip (5) on a bottom, and the metal layer on chip (5) has a protruding and/or recessing structure.

11. The wide band gap semiconductor device as claimed in claim 10 wherein the protruding and/or recessing structure of the metal layer on chip (5) are pits uniformly distributed on a surface of the metal layer on chip (5), or projecting barbs uniformly distributed on the surface of the metal layer on chip (5).

12. The wide band gap semiconductor device as claimed in claim 4 wherein internal side walls of the recessed slot structure (4) are outward inclined, forming a recessed slot (41) with a wider opening and a narrower bottom.

13. The wide band gap semiconductor device as claimed in claim 12 wherein the bottom of the recessed slot structure (4) and the internal side walls in part or in whole have recessed slot metal layer (42), the recessed slot metal layer (42) extends to surfaces of the base mount (2) around the opening of the recessed slot structure (4).

14. The wide band gap semiconductor device as claimed in claim 13 wherein the recessed slot metal layer (42) consists of a single layer or multiple layers, and a top layer of the recessed slot metal layer (42) has a protruding and/or recessing structure.

15. The wide band gap semiconductor device as claimed in claim 12 wherein the recessed slot structure (4) comprises the recessed slot (41) designed on the base mount (2), and a metal conductor (43), the metal conductor (43) fills up the recessed slot (41), and further extends to an outside of the recessed slot (41); and
wherein there is a conductor recessed slot (44) designed on the metal conductor (43).

16. The wide band gap semiconductor device as claimed in claim 15 wherein a surface of the metal conductor (43) has a protruding and/or recessing structure.

17. The wide band gap semiconductor device as claimed in claim 1 wherein there is a distance, denoted as L, between position A, where an outward inclination of a bottom of the chip (1) will extend to and intersect with a bottom of the base mount (2), and position B, an outer edge of the base mount (2).

18. The wide band gap semiconductor device as claimed in claim 17 wherein the outward inclination from the bottom of the chip (1) will extend to and intersect with the bottom of the base mount (2), at an angle within a range of 25° to 65°.

19. The wide band gap semiconductor device as claimed in claim 13 wherein there is a distance, denoted as L′, between position C, where an outer inclination from a bottom of the chip (1) will extend to and intersect with a top of the base mount (2), and position D, an outer edge of the recessed slot metal layer (42).

20. The wide band gap semiconductor device as claimed in claim 19 wherein heat sinks (6) are designed at a bottom of the base mount (2).

21. The wide band gap semiconductor device as claimed in claim 1 wherein the wide band gap semiconductor material is silicon carbide.

22. A fabrication method for wide band gap semiconductor devices wherein a recessed slot structure (4) is designed on a base mount (2) made of wide band gap semiconductor materials, a thermally conductive layer (3) is formed by filling up the recessed slot structure (4) with a metal powder, and a chip (1) with a substrate made of wide band gap semiconductor materials is placed on the thermally conductive layer (3) by the recessed slot structure (4); and
wherein by sintering or welding, a capacity of dissipating heat and/or conducting electricity arises between the thermally conductive layer (3) and the chip (1), and between the thermally conductive layer (3) and the base mount (2), forming a wide band gap semiconductor device.

23. The fabrication method for wide band gap semiconductor devices as claimed in claim 22 wherein a pressure sintering process or a vacuum sintering process is adopted in a sintering process.

24. The fabrication method for wide band gap semiconductor devices as claimed in claim 22 wherein a thickness of the thermally conductive layer (3) is controlled by a slot depth of the recessed slot structure (4).

25. The fabrication method for wide band gap semiconductor devices as claimed in claim 22 wherein a sintering process is implemented in an inert gas atmosphere, at 230° C. to 330° C., by imposing a 5 to 40 MPa/cm² pressure on the chip (1) and continuously heating for 20 to 30 minutes.

26. The fabrication method for wide band gap semiconductor devices as claimed in claim 25 wherein the sintering process is implemented in an inert gas atmosphere, at 250° C., by imposing a 30 MPa/cm² pressure on the chip (1) and continuously heating for 30 minutes.

27. The fabrication method for wide band gap semiconductor devices as claimed in claim 22 wherein when a particle size of the metal powder is at nano scale, a sintering process is implemented in an inert gas atmosphere, at 180° C. to 280° C., by imposing a 5 to 40 MPa/cm² pressure on the chip (1) and continuously heating for 20 to 35 minutes.

28. The fabrication method for wide band gap semiconductor devices as claimed in claim 22 wherein before a sintering process, a metal layer on chip (5), which is capable of conducting electricity, is plated on a bottom of the chip (1) in advance, and the metal layer on chip (5) has a protruding and/or recessing structure.

29. The fabrication method for wide band gap semiconductor devices as claimed in claim 22 wherein before a sintering process, a recessed slot (41) is made on the base mount (2) first, and then recessed slot metal layer (42) is plated on the recessed slot (41), in order to form the recessed slot structure (4), the recessed slot (41) is designed as a recessed slot with a wider opening and a narrower bottom, and the recessed slot metal layer (42) has a protruding and/or recessing structure.
